(19) United States
(12) Patent Application Publication
(10) Pub. No.: US 2013/0248975 A1
(43) Pub. Date: Sep. 26, 2013

(54) NON-VOLATILE SEMICONDUCTOR MEMORY DEVICE AND ITS MANUFACTURING METHOD

(71) Applicants: Tomoo HISHIDA, Kanagawa-ken (JP); Yoshihisa Iwata, Kanagawa-ken (JP)

(72) Inventors: Tomoo HISHIDA, Kanagawa-ken (JP); Yoshihisa Iwata, Kanagawa-ken (JP)

(73) Assignee: KABUSHIKI KAISHA TOSHIBA, Tokyo (JP)

(21) Appl. No.: 13/607,702

(22) Filed: Sep. 8, 2012

(30) Foreign Application Priority Data
Mar. 22, 2012 (JP) P2012-066237

(51) Int. Cl. H01L 29/792; H01L 21/28

(52) U.S. Cl. 257/324; 438/585; 257/E21.19; 257/E29.309

(57) ABSTRACT

A non-volatile semiconductor memory device includes a peripheral circuit having multilayer wirings. Above this peripheral circuit, a plurality of memory strings is formed. The memory strings include a plurality of memory cells and a back gate transistor connected in series. Multiple back gate layers are formed to function as a control electrode of the back gate transistor. A first connection part composed of semiconductor films connects a lower surface of one of the back gate layers and an upper surface of the uppermost wiring layer of the multilayer wirings, and a barrier metal film is disposed above the uppermost wiring layer.

### CROSS-REFERENCE TO RELATED APPLICATION

This application is based upon and claims the benefit of priority from Japanese Patent Application No. 2012-066237, filed Mar. 22, 2012; the entire contents of which are incorporated herein by reference.

### FIELD

Embodiments described herein relate to a non-volatile semiconductor memory device and its manufacturing method.

### BACKGROUND

In traditional large scale integration (LSI), the components are integrated on top of a silicon substrate which provides a flat surface. Because of this, in order to increase the storage capacity of the memory, one of the components has to be smaller (miniaturization). However, in recent years, this miniaturization has become difficult in terms of cost and innovation.

In order to solve the problems described above, memory layers are laminated in 3 dimensions and are processed in bulk. The current manufacturing technology for 3D-stacked memory has been developed around these procedures.

### DESCRIPTION OF THE DRAWINGS

FIG. 1 is a block diagram of a non-volatile semiconductor memory device according to a first embodiment.

FIG. 2 is a three-dimensional perspective diagram of the non-volatile semiconductor memory device of the first embodiment.

FIG. 3 is a figure showing the structure of the non-volatile semiconductor memory device of the first embodiment.

FIG. 4 is an enlarged figure of the NAND strings shown within the dashed box in FIG. 3.

FIG. 5 is a figure showing the structure of a non-volatile semiconductor memory device of a comparative example.

FIG. 6 is a cross-sectional view explaining the manufacturing method of the non-volatile semiconductor memory device of the first embodiment.

FIG. 7 is a cross-sectional view illustrating the manufacturing method of the non-volatile semiconductor memory device of the first embodiment after the step in FIG. 6.

FIG. 8 is a cross-sectional view illustrating the manufacturing method of the non-volatile semiconductor memory device of the first embodiment after the step illustrated in FIG. 7.

FIG. 9 is a cross-sectional view illustrating the manufacturing method of the non-volatile semiconductor memory device of the first embodiment after the step in FIG. 8.

FIG. 10 is a cross-sectional view illustrating the manufacturing method of the non-volatile semiconductor memory device of the first embodiment after the step in FIG. 9.

FIG. 11 is a cross-sectional view illustrating the manufacturing method of the non-volatile semiconductor memory device of the first embodiment after the step in FIG. 10.

FIG. 12 is a cross-sectional view illustrating the manufacturing method of the non-volatile semiconductor memory device of the second embodiment.

FIG. 13 is a cross-sectional view illustrating the manufacturing method of the non-volatile semiconductor memory device of the second embodiment after the step in FIG. 12.

FIG. 14 is a cross-sectional view illustrating the manufacturing method of the non-volatile semiconductor memory device of the third embodiment.

FIG. 15 is a cross-sectional view illustrating the manufacturing method of the non-volatile semiconductor memory device of the third embodiment after the step shown in FIG. 14.

FIG. 16 is a cross-sectional view illustrating the manufacturing method of the non-volatile semiconductor memory device of the third embodiment after the step shown in FIG. 15.

FIG. 17 is a cross-sectional view illustrating the manufacturing method of the non-volatile semiconductor memory device of the fourth embodiment.

FIG. 18 is a cross-sectional view illustrating the manufacturing method of the non-volatile semiconductor memory device of the fourth embodiment after the step shown in FIG. 17.

FIG. 19 is a cross-sectional view illustrating the manufacturing method of the non-volatile semiconductor memory device of the fourth embodiment after the step shown in FIG. 18.

FIG. 20 is a figure showing the structure of the non-volatile semiconductor memory device of the fifth embodiment.

FIG. 21 is a figure showing the structure of the non-volatile semiconductor memory device of the fifth embodiment.

FIG. 22 is a figure showing the structure of the non-volatile semiconductor memory device of the fifth embodiment.

FIG. 23 is a figure showing the structure of the non-volatile semiconductor memory device of the fifth embodiment.

FIG. 24 is a figure showing the structure of the non-volatile semiconductor memory device of the fifth embodiment.

FIG. 25 is a figure showing the structure of the non-volatile semiconductor memory device of the fifth embodiment.

### DETAILED DESCRIPTION

In general, certain embodiments of this invention will be explained by referring to the drawings.

According to a first embodiment, there is provided a non-volatile semiconductor memory device which enables the suppression of an increase in resistance between wiring layers of the uppermost layer of the peripheral circuit and a back gate layer, as well as its manufacturing method.

The non-volatile semiconductor memory device of this embodiment includes a peripheral circuit having multilayer wirings. Above this peripheral circuit, a plurality of memory strings is formed. The memory strings include a plurality of memory cells and a back gate transistor connected in series. Multiple back gate layers are formed to function as a control electrode of the back gate transistor. A first connection part composed of semiconductor films connects a lower surface of one of the back gate layers and an upper surface of the uppermost wiring layer of the multilayer wirings, and a barrier metal film is disposed above the uppermost wiring layer.

The manufacturing method of the non-volatile semiconductor memory device of this embodiment includes forming a peripheral circuit having a multilayer wiring on the surface of a substrate, forming a first interlayer dielectric film on top of the peripheral circuit, forming a connection hole through the first interlayer dielectric film which reaches an uppermost wiring layer of the multilayer wiring, removing a part of the upper surface of the first interlayer dielectric film to form a groove in the first interlayer dielectric film, forming a barrier metal film on one or more surfaces of the connection hole and surfaces of the first interlayer dielectric film, and filling the connection hole and at least a portion of the groove with one or more conductive materials to form a gate layer in the groove and a conductive coupling in the connection hole, the conductive coupling providing electrical conductivity between the gate layer and the uppermost wiring layer of the multilayer wirings.

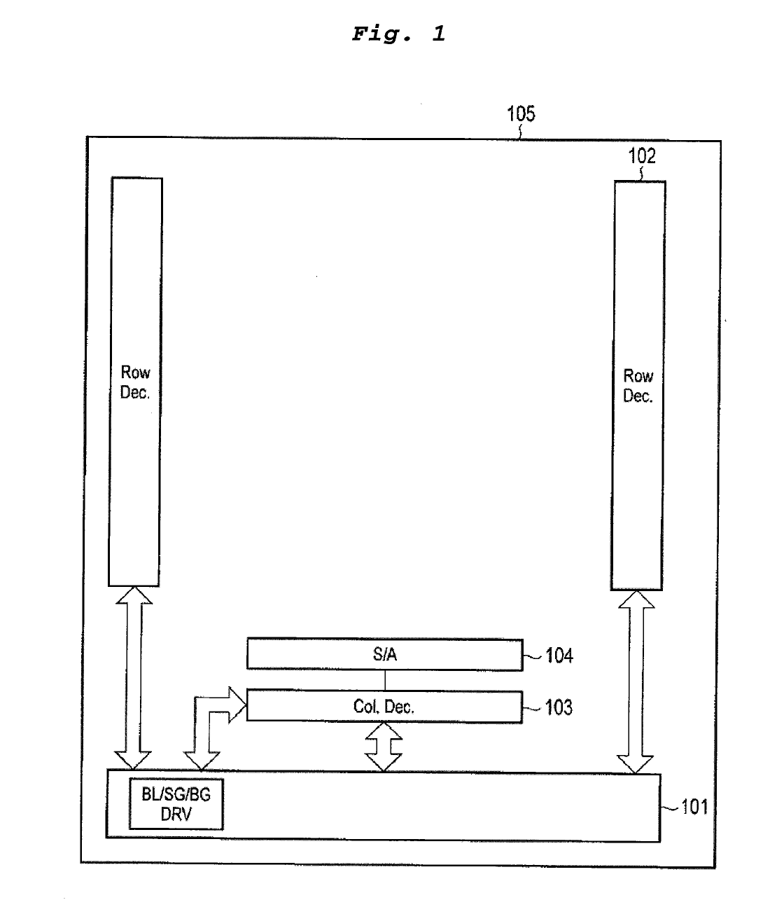

FIG. 1 shows a block diagram of the non-volatile semiconductor memory device of the first embodiment.

The non-volatile semiconductor memory device of the first embodiment includes a control device (drive unit) 101, a row decoder 102, a column decoder 103, a sense amplifier 104, and a memory array 105.

Below the memory array 105, a peripheral circuit such as the control device 101, the row decoder 102, the sense amplifier 104, etc., is formed. The peripheral circuit includes the multilayer wirings which will be explained later. Under the memory array 105, by appropriately configuring the peripheral circuit, it is possible to miniaturize the flat or die size of the chip. This is not limited to configuring the entire peripheral circuit under the memory array 105; it is also possible to miniaturize by configuring a part of the peripheral circuit.

The control device 101 is configured to control the row decoder 102, the column decoder 103, and the sense amplifier 104 by generating the voltage supplied to the memory cells when a write operation, a read operation or an erase operation, depending on the addresses supplied from the outside.

The row decoder 102 is controlled by the control device 101 and is configured to select the word line WL.

The column decoder 103 is controlled by the control device 101 and is configured to select the bit line BL through the sense amplifier 104.

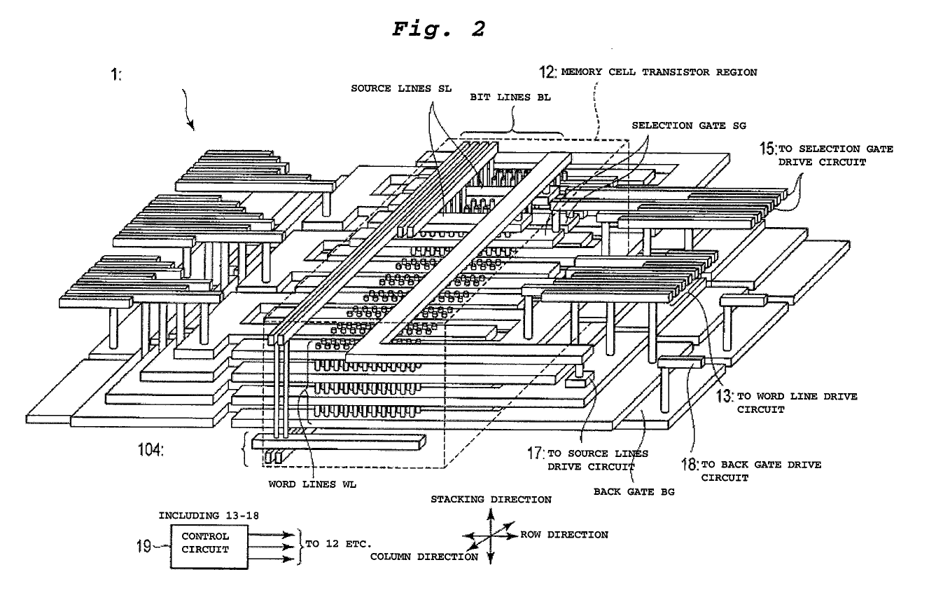

The memory array 105 includes multiple blocks. These blocks respectively include multiple memory cells arranged in matrix. A plurality of word lines WL are extending in a first direction (labeled as “row direction” in FIG. 2). A plurality of bit lines BL are extending in a second direction that is orthogonal to the first direction (labeled as “column direction” in FIG. 2). Each memory cell electrically connects both one of the word lines WL and one of the bit lines BL.

The sense amplifier 104 is controlled by column decoder 103; it is configured to amplify the data which has been read out from every page of memory cells. It should be noted that the sense amplifier 104 can be integrated so as to be included within the column decoder 103.

FIG. 2 shows a schematic block diagram of the non-volatile semiconductor memory device of the first embodiment.

The non-volatile semiconductor memory device of the first embodiment includes a memory cell transistor region 12, multiple word line drive circuit 13, multiple gate selection drive circuit 15, multiple source line drive circuit 17 and back gate transistor drive circuit 18, etc. The control circuit 19 is configured by the word line drive circuit 13, selection gate drive circuit 15, source line drive circuit 17 and back gate transistor drive circuit 18.

It should be noted that the control circuit 19 in FIG. 2 has almost the same meaning as control device 101, row decoder 102, column decoder 103 and sense amplifier 104 in FIG. 1, and memory cell transistor 12 in FIG. 2 has almost the same meaning as memory array 105 in FIG. 1. More precisely, as an example for the first embodiment, the control circuit 19 is placed outside the memory cell transistor region 12 (memory array 15).

On the memory cell transistor region 12, multiple word lines WL, multiple bit lines BL, multiple source lines SL, back gate layer BG and multiple selection gates SG are provided. On this memory cell transistor region 12, the memory cell transistor is located at a part corresponding to the intersection between one of the stacked word lines WL and the U-shaped silicon columns SP. This transistor region will be described in greater detail later on. It should be noted that, in FIG. 2, there are four stacked word lines WL. However this configuration and number of word lines may be different as well and this embodiment is not so limited.

Word line drive circuit 13 controls the voltage which is applied to the word lines WL. Also, all the wirings which connect word line drive circuit 13 to word lines WL are formed by wiring layers of the same level. However, this configuration is not required, and it is also possible to form the wirings by using wiring layers from different levels. In addition, a bit line drive circuit (not shown) controls the voltage applied on bit lines BL.

Source line drive circuit 17 controls the voltage that is connected and applied to source lines SL. The depicted source line drive circuit 17 is connected to all source lines SL, but this configuration is not required. It is also possible to provide a unique source line drive circuit 17 for each source line.

Back gate transistor drive circuit 18 controls the voltage that is connected and applied to the back gate layer BG.

Selection gate SG drive circuit 15 controls the voltage that is connected and applied to selection gate SG.

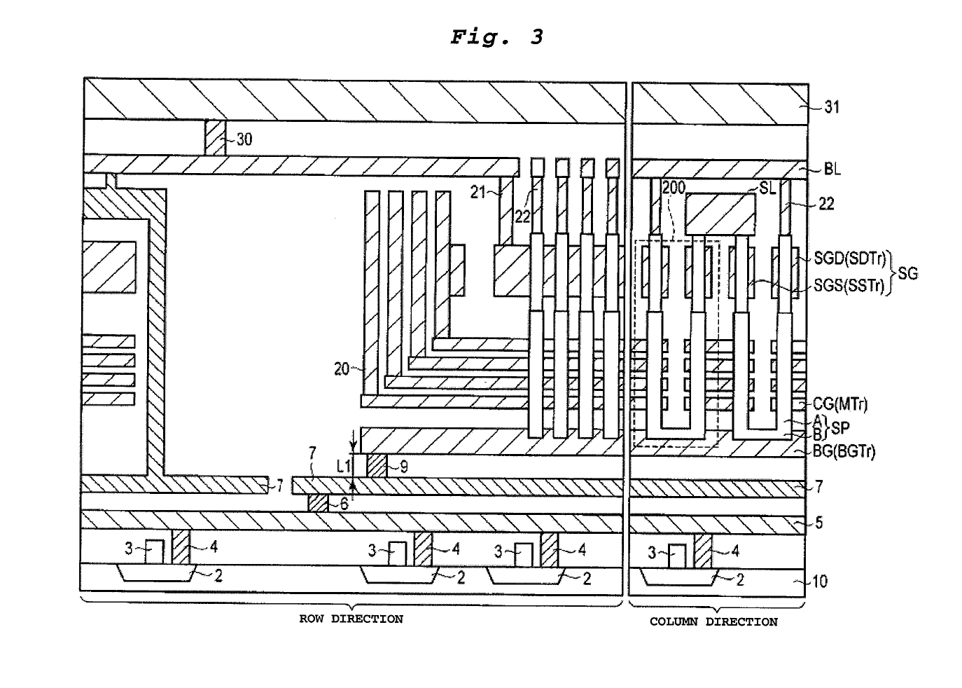

FIG. 3 shows the structure of the memory cell transistor region and peripheral circuit region. FIG. 3 is a surface view of the memory cell transistor region and the peripheral circuit region which is located below the memory cell transistor region. FIG. 3 is a figure which is viewed from the column direction and row direction depicted previously in FIG. 2. It should be noted that, in FIG. 3, the interlayer dielectric film is omitted. FIG. 4 is a figure focusing on the NAND strings shown in FIG. 3.

Within the peripheral circuit region, a region 2 (AA region) is formed at various parts of the surface of the substrate 10. This region 2 forms a transistor which constitutes the peripheral circuit. Substrate 10 may be, for example, a silicon substrate.

AA region 2 comprises a pair of source/drain regions (not shown) and a channel region (not shown). Gate part 3, which includes gate insulating film and a gate electrode, is formed on the channel region. On the other side of source/drain region, plug 4 is formed.

Plug 4 is connected to wiring layer 5 of the lowermost layer of the multilayer wirings in the peripheral circuit. Wiring layer 5 is connected to wiring layer 7, the uppermost layer of multilayer wirings, through plug 6. Here, for the sake of simplicity, a 2-layer type of multilayer wirings is used, but it is also possible to use a 3-layer type or a type with even more layers.

On the memory cell transistor region 12 over the peripheral circuit region of the substrate 10, multiple NAND strings 200 (memory cell strings), are formed. The NAND strings 200 include U-shaped silicon columns. Each NAND string 200 includes two selection transistors (drain-side selection transistor SDTr and source-side selection transistor SSTr) formed above multiple memory cell transistors MTr and on their both ends.

Multiple memory cell transistors MTr are formed at a part corresponding to the intersections between U-shaped silicon columns SP and multiple control gates CG (word lines WL). The memory cell transistors MTr are connected in series to current paths.

As shown in FIG. 4, each memory cell transistor MTr includes memory film 324 between U-shaped silicon columns SP and control gates CG. This memory film 324 may be composed of, for example, a layer of tunnel insulating film 322, a charge storage layer 321 and block insulating film 320. Each of these layers, 320-322 may be unique layers and distinct layers. Also, each memory cell transistor MTr has a MONOS structure.

Drain side selection transistor SDTr is formed at apart corresponding to the intersection between U-shaped silicon columns SP and drain-side selection gate SGD. On the other hand, source-side selection transistor SSTr is formed at apart corresponding to the intersection of U-shaped silicon columns SP and source-side selection gate SGS. As shown in FIG. 4, drain-side selection transistor SDTr and source-side selection transistor SSTr each have the MONOS structure that also characterizes memory cell transistor MTr. Drain side selection transistor SDTr and source-side selection transistor SSTr may also have, instead of a MONOS structure, a normal gate structure (gate insulating film, gate electrode).

Also, drain-side selection transistor SDTr and source-side selection transistor SSTr are formed above multiple memory cell transistors MTr. Source side selection transistor SSTr is then connected to one edge of the multiple memory cell transistors MTr and is connected to source lines SL on the other edge. On the other hand, drain-side selection transistor SDTr is connected to the remaining edge of memory cell transistors MTr and also is connected to bit lines BL on the other edge.

U-shaped silicon columns SP are formed as U-shaped configuration by the cross section in the column direction. These U-shaped silicon columns SP include a pair of columns A which extend in the stacking direction and a pipe B (connection part), which is connected to the bottom edge of the pair of columns A. The pipe B is provided by a back gate layer BG, and forms part of back gate transistor BGTr. A back gate layer BG is formed in order to connect to each pipe B of multiple memory strings MTr; it functions as a control electrode of back gate transistor BGTr, which forms channels in pipe B.

Also, U-type Silicon columns SP are placed so that the straight line which passes through the central axis of a pair of columns A, is parallel to the column direction. U-shaped silicon columns SP are then placed in order to become a matrix which is in-plane in the row direction and column direction. In addition, as shown in FIG. 4, U-shaped silicon columns SP include a hollow gap H1; this hollow gap H1 is filled with insulation 325.

Multiple control gates CG are stacked above back gate layers BG and are placed in order to intersect U-shaped silicon columns SP. Each control gate CG extends lengthwise in the row direction and is connected to leader line 20. Also, each control gate CG is formed in order to be shared by the adjacent two columns A of U-shaped silicon columns SP on two adjacent NAND strings 200 in the column direction.

It should be noted that, according to FIG. 3, an example with control gate CG being stacked four times is shown, but other levels of stacking may also be used, and this disclosure is not limited to only four stacked control gates. Also, although not shown in the drawings, odd numbers of control gates CG in the column direction are gathered in a bundle on one edge in the row direction of every block. On the other hand, even numbers of control gates CG in the column direction are gathered in a bundle on the other edge in the row direction of every block.

A back gate layer BG is provided under the bottom of the lowermost word line WL. A back gate layer BG is formed in a row/column plane, and is sufficiently large to cover pipe B of U-shaped silicon columns SP.

Drain side selection gate SGD and source-side selection gate SGS are provided above the uppermost part of control gate CG. The drain-side selection gate SGD and source-side selection gate SGS extend lengthwise in the row direction. Also drain-side selection gate SGD and source-side selection gate SGS are formed in order to intersect each column A of U-shaped silicon columns SP. They are separated from each other in the column direction and will be formed as lengthwise bodies, with space existing between the two.

Source lines SL are provided above selection gates SGD and SGS. Source lines SL are formed in order to be shared with adjacent two columns A, where the two columns are associated with neighboring U-shaped silicon columns SP, and where each of the columns is associated with one of an adjacent pair of NAND strings 200. The configuration is such that the NAND strings are disposed in the column direction. Source lines SL are parallel to each other and extend lengthwise in the row direction. Each source line SL is separated from the other source line in the column direction by a gap, and is formed in lines and spaces.

Multiple bit lines BL are disposed above top of source lines SL. Each bit line BL extends lengthwise in the column direction, and is separated from other bit lines in the row direction by a gap. Bit lines BL are connected to top metal layer (for example aluminum layer) 31 through plug 30.

Wiring layer 7 is disposed below back gate layer BG. Wiring layer 7 is part of the uppermost layer of the peripheral circuit. Connection parts 9 are disposed between the lower face of back gate layer BG and the upper face of wiring layer 7. Back gate layer BG is connected to wiring layer 7 through the connection parts 9. The height L1 of connection parts 9 may be, for example, 10-100 nm. With such a length, resistance between back gate layer BG and wiring layer 7 due to the connection parts 9 is kept low.

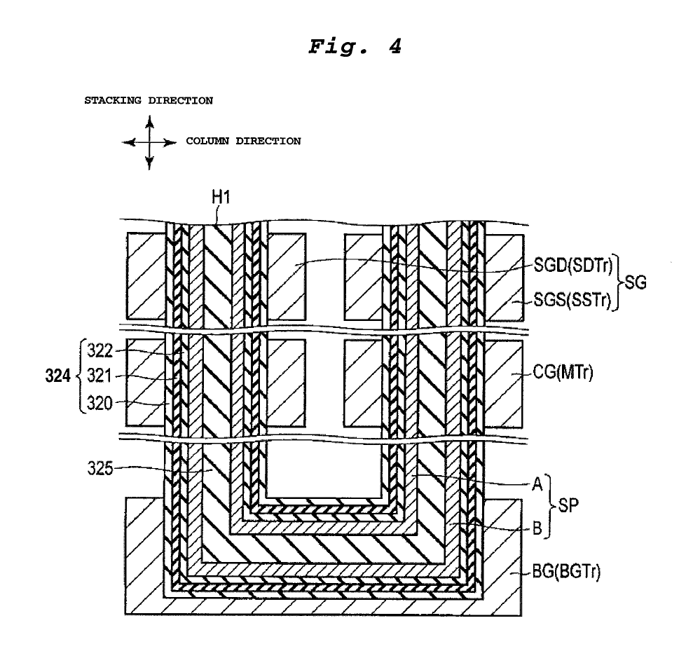

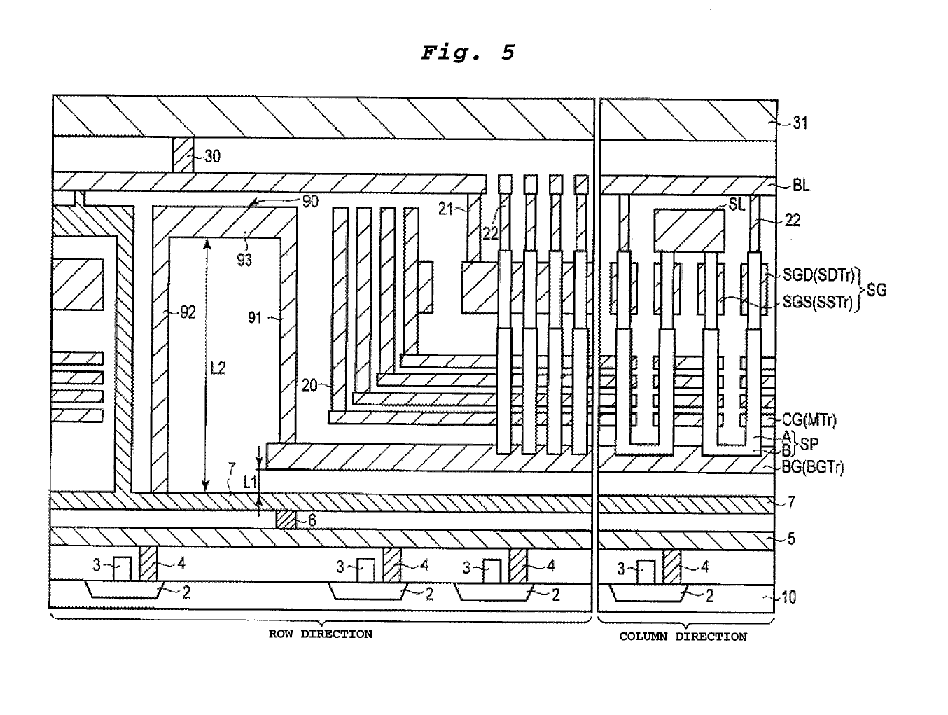

For the purposes of comparison with the non-volatile semiconductor memory device in the first embodiment of FIG. 3, a comparative example is illustrated by the cross-sectional view of an example non-volatile semiconductor memory device in FIG. 5. The difference between the comparative example and the first embodiment is the method of connecting of the back gate layer BG to wiring layer 7.

Connection part 90 in the comparative example includes plug 91 in FIG. 5, which extends upwards from the upper face of the back gate layer BG, and plug 92, which is disposed between the upper face of wiring layer 7 and the lower part of wiring layer 93. Wiring layer 93 is used to connect the upper edge of plug 92 and the upper edge of plug 91. Here, the height L2 of plug 92 is a few μm. Therefore, the resistance (parasitic resistance) of connection part 90 between wiring layer 7 and the bag gate layer BG is higher in the comparative example because of the inclusion of plug 92, plug 91, and the wiring layer.

In contrast, in the case of the first embodiment of the present disclosure, the connection part 9 is short. This shortness enables suppression of parasitic resistance.

Also, in the case of the comparative example, in order to form high plugs 91 and 92, it is necessary to form deep connection holes on the interlayer dielectric film. If this type of deep connection holes is formed only in the needed quantity, variability in the depth of connection holes is likely to occur more easily. This can lead to variation in resistance and might adversely affect device properties. In contrast, because the height of connection part 9 is low in the first embodiment, the variation in resistance can be suppressed.

Next, referring again to the comparative examples, because an interlayer dielectric film (not shown) is present between high plug 92 of the adjacent connection part 90 and high plug 91, there may be a problem of an increase in the parasitic capacitance.

In the case of the first embodiment of this disclosure, the connection part 9 is short. Because of shortness, more than two connection parts 9 are formed, which can facilitate the suppression of parasitic capacitance. As described above, because it is also possible to suppress the increase in parasitic resistance, it is possible to configure connection part 9 which serve both to restrain the effects of parasitic resistance and parasitic capacitance therein, as well as in back gate layer BG. As described previously, these resistive elements are connected to a transistor formed on the peripheral circuit region of the surface of the substrate by region 2 AA.

Referring again to the comparative example, among the memory cell transistor regions, only the divided regions between the memory cell transistor regions 12 are configured to connect back gate layer BG to wiring layer 7 through connection part 90. This constraint does not exist in the first embodiment.

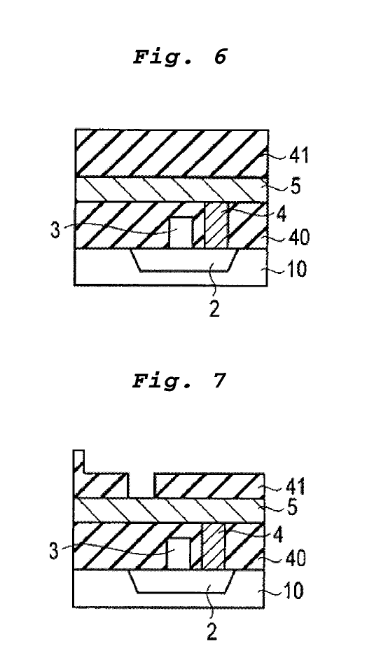

FIG. 6 to FIG. 11 are cross-sectional diagrams that explain the manufacturing method of the non-volatile semiconductor memory device of the first embodiment.

First of all, as shown in FIG. 6, on the surface of substrate 10, and above AA region 2, gate part 3 is formed. Subsequently, interlayer dielectric film 40, plug 4, wiring layer 5 and interlayer dielectric film 41 are formed.

As shown in FIG. 7, connection holes and wiring grooves (space which will later contain wiring) are then formed through and on interlayer dielectric layer 41 by using lithographic exposure technology, respectively.

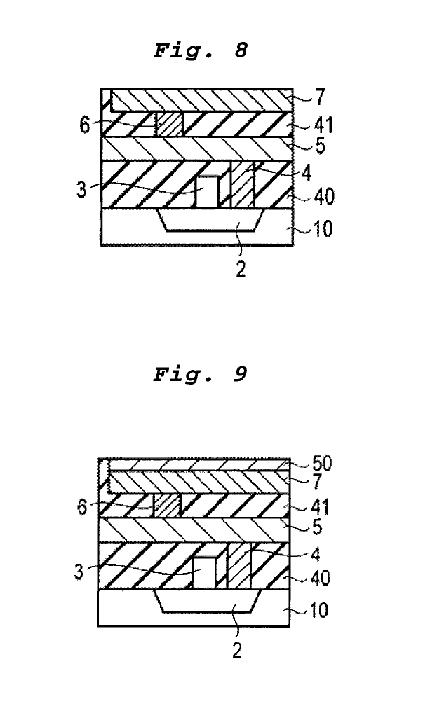

The next step is, as shown in FIG. 8, to fill the connection holes and wiring grooves, thereby forming a conductive layer in plug 6 and forming wiring layer 7 above top of the interlayer dielectric film 41 and the plug 6. Plug 6 and wiring layer 7 are formed by using the CMP (Chemical Mechanical Polishing) process and by flattening the conductive film. At this stage, in order to make the upper face of wiring layer 7 lower than the opening surface of the wiring groove, the CMP process is conducted (over-polish). Wiring layer 7 can be formed of, for example, a metal with a high melting point, such as metal wiring materials like W (tungsten), etc.

As shown in FIG. 9, by using the CMP process, the wiring grooves are embedded by barrier metal film 50. The barrier metal film 50 can be, for example, a tantalum nitride film. The tantalum nitride film has the ability to prevent the diffusion of metals having a high melting point. The tantalum nitride film is also difficult to oxidize.

Due to the fact that it is difficult to oxidize, it is possible to suppress the oxidation of wiring layer 7 that occurs when using oxygen during the manufacturing process. This process can occur, for example, when using oxygen in order to form an interlayer dielectric film.

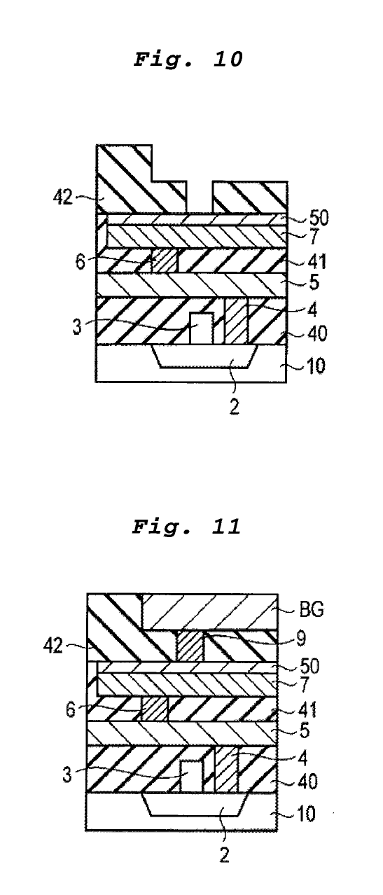

The next step, as shown in FIG. 10, is to form an interlayer dielectric film 42 on the top surface of barrier metal film 50. Subsequently, connection holes and grooves (the grooves in which the back gate layer BG is later disposed) are formed in and on the interlayer dielectric film 42, respectively.

When silicon oxide film is used as an interlayer dielectric film 42 above barrier metal 50, the oxidation of wiring layer 7 can be suppressed. Because of this, it is possible to suppress the increase in resistance (wiring resistance/interconnection resistance) of wiring layer 7.

The next step involves, as shown in FIG. 11, forming a conductive film and back gate layer which embedded the connection holes and fill the grooves of the interlayer dielectric film 42, respectively. This results in the formation of connection part 9, which is surrounded by dielectric film 42, and back gate layer BG on top of interlayer dielectric film 42. During this process, connection part 9 and back gate layer BG are formed by flattening the conductive film and by using the CMP process.

Well-known processes such as the NAND string forming process, source line SL forming process, and bit line BL forming process, etc., are then carried out.

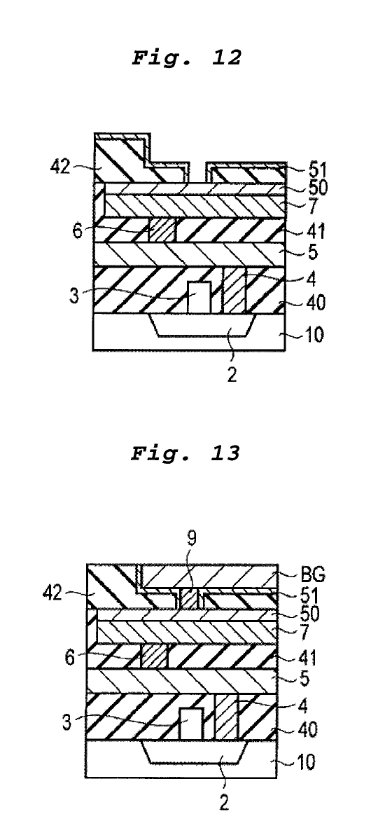

FIG. 12 and FIG. 13 are cross-sectional views illustrating the manufacturing method of the non-volatile semiconductor memory device of the second embodiment.

First of all, the processes in FIG. 6 to FIG. 10 are carried out.

After that, as shown in FIG. 12, barrier metal film 51 is formed on the entire surface in order to cover the inner faces of connection holes and grooves of interlayer dielectric film 42. Barrier metal film 51 can be a tantalum nitride film, for example.

As shown in FIG. 13, after forming a conductive film from connection part 9 and back gate layer BG above top of interlayer dielectric film 42 and the connection part 9, while forming connection part 9 and back gate layer BG by flattening the conductive film by using the CMP process. The next step is to remove the exposed parts of barrier metal 51 found on the uppermost surface of interlayer dielectric film 42. After this, well-known processes are carried out.

According to the second embodiment, it is possible to effectively suppress the increase in diffusion and wiring resistance of metals with high melting points.

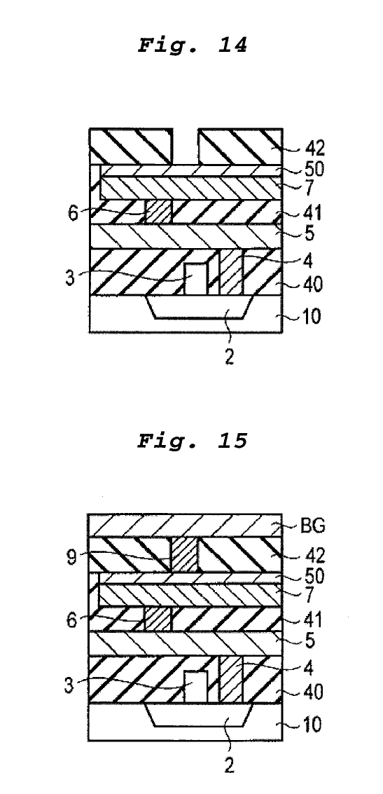

FIG. 14 to FIG. 16 are cross-sectional views illustrating the non-volatile semiconductor memory device of the third embodiment.

First of all, the processes illustrated in FIG. 6 to FIG. 9 are carried out.

The next step is to form an interlayer dielectric film 42 on the surface of barrier metal film 50. As shown in FIG. 14, and after forming interlayer dielectric film 42, connection holes are then formed through this film.

As shown in FIG. 15, in order to fill the connection hole and cover the interlayer dielectric film 42, connection parts 9 are formed in the connection holes and back gate layer BG is then formed above the interlayer dielectric film 42 and the connection parts 9.

After that, as shown in FIG. 16, back gate layer BG is processed by using, for example, the RIE (Reactive Ion Etching) process in order to give it a predetermined shape. After this, the well-known processes for fabricating semiconductor devices are continued.

A polycrystalline silicon film (semiconductor film) which contains impurities can be used in order to form connection part 9 and back gate layer BG by using the RIE process rather than the CMP process.

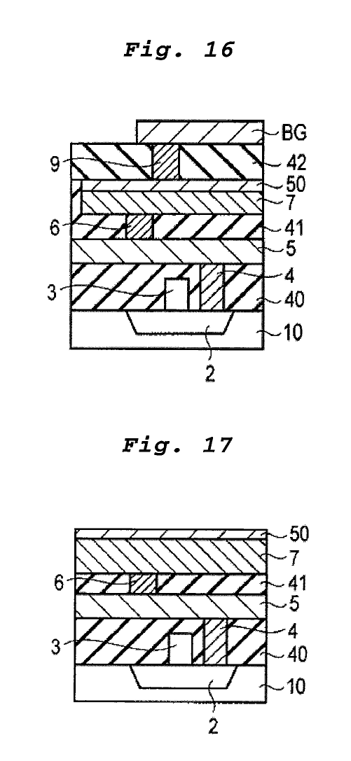

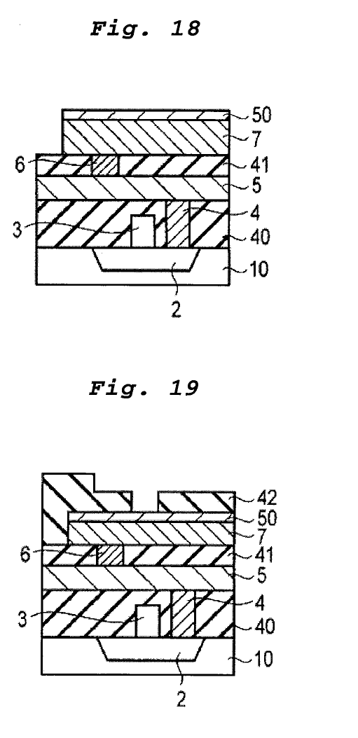

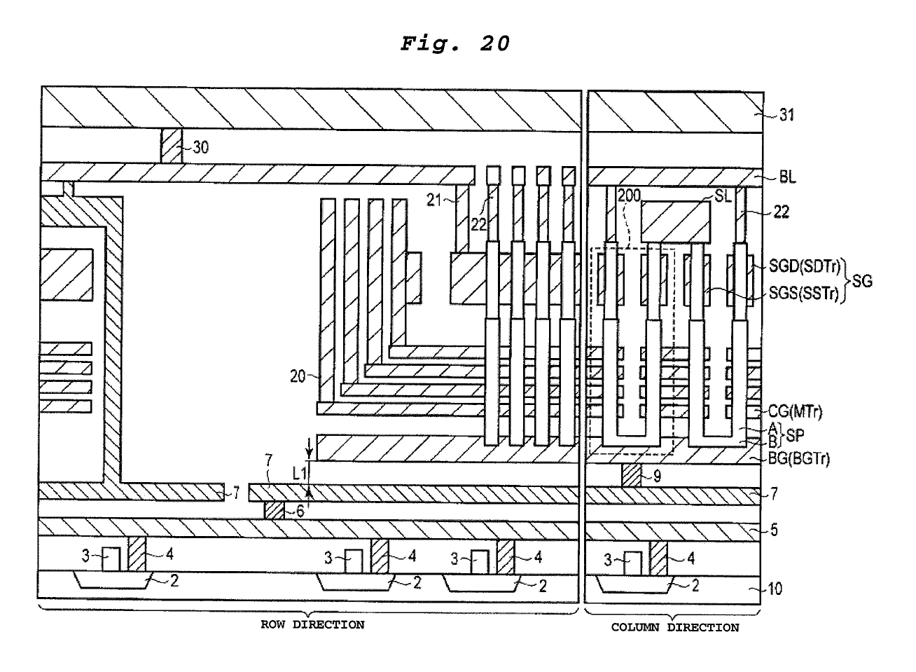

FIG. 17 to FIG. 19 are cross-sectional views illustrating the manufacturing method of the non-volatile semiconductor memory device according to the fourth embodiment.

First of all, the processes resulting in the configuration shown in FIG. 6 are carried out.

As shown in FIG. 17, after forming plug 6 through interlayer dielectric film 41, wiring layer 7 and barrier metal film 50 are successively formed.

After that, as shown in FIG. 18, wiring layer 7 and barrier metal film 50 are processed into a pre-determined shape using the RIE process.

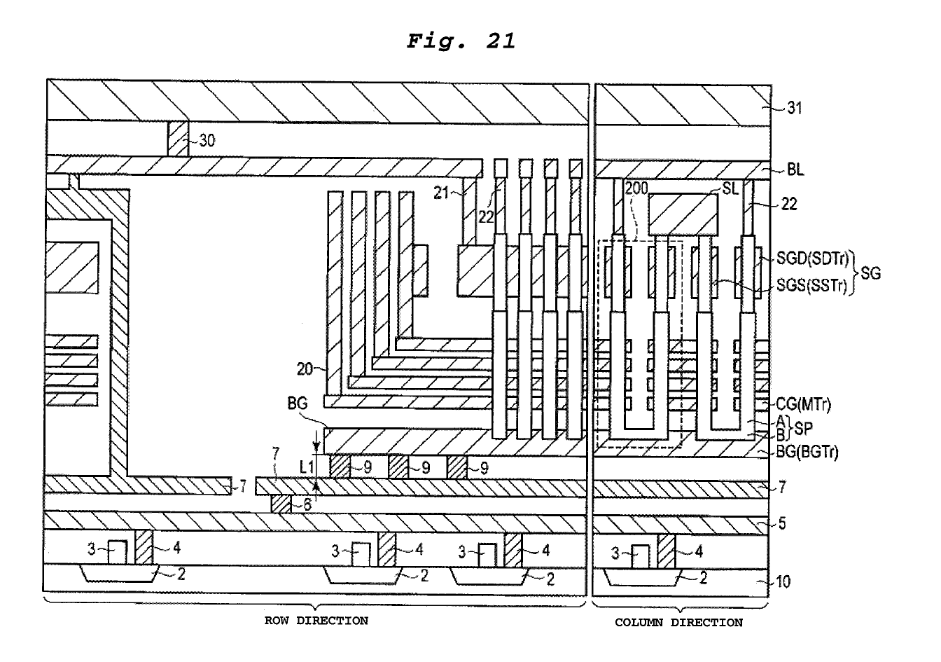

The next step is to form an interlayer dielectric film 42 on and around wiring layer 7 and barrier metal film 50. Next, as shown in FIG. 19, connection holes and grooves are formed through and on the interlayer dielectric film 42, respectively. After that, the processes described with reference to FIG. 12 and FIG. 13 are carried out.

Aluminum wiring, for example, can be used in order to form wiring layer 7 by using the RIE process rather than the CMP process.

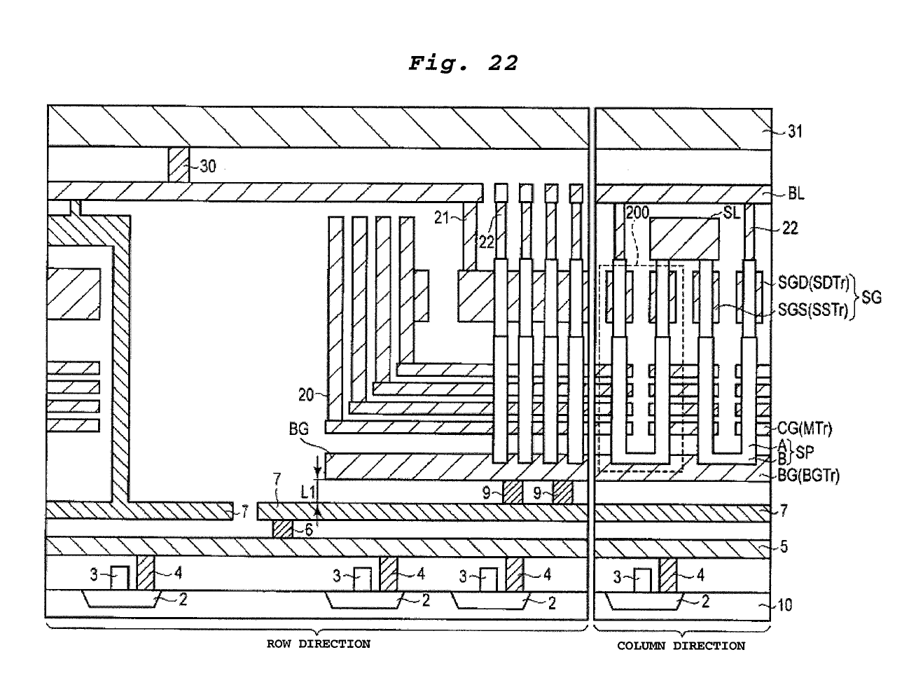

The non-volatile semiconductor memory device according to the fifth embodiment will now be explained. FIG. 20 to FIG. 25 are figures showing the structure of the non-volatile semiconductor memory device according to the fifth embodiment. They are drawn from the same perspective as FIG. 3. In the explanation of FIG. 20 to FIG. 25, only the necessary reference characters are shown.

In FIG. 3, the structure of back gate layer BG and wiring layer 7 connected by connection part 9 is shown only in the row direction but, as shown in FIG. 20, the back gate layer BG and wiring layer 7, which are mutually connected by connection part 9, may alternatively be disposed in the column direction.

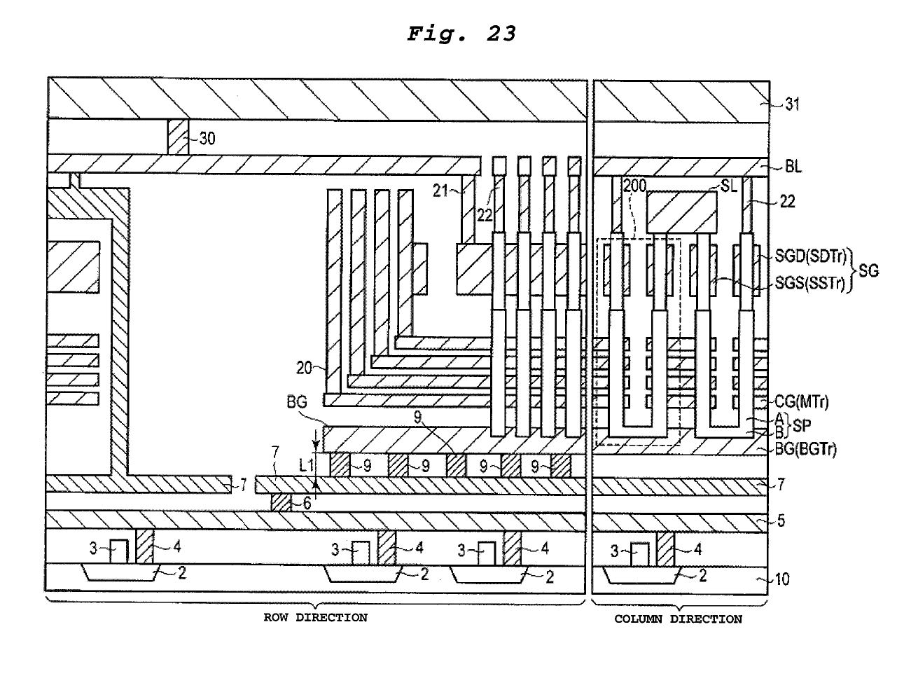

Also, in FIG. 3, the structure of back gate layer BG and wiring layer 7 is shown to be connected by a single connection part 9. However, as shown in FIG. 21 to FIG. 25, it is also possible for back gate layer BG and wiring layer 7 to be connected by multiple connection parts 9.

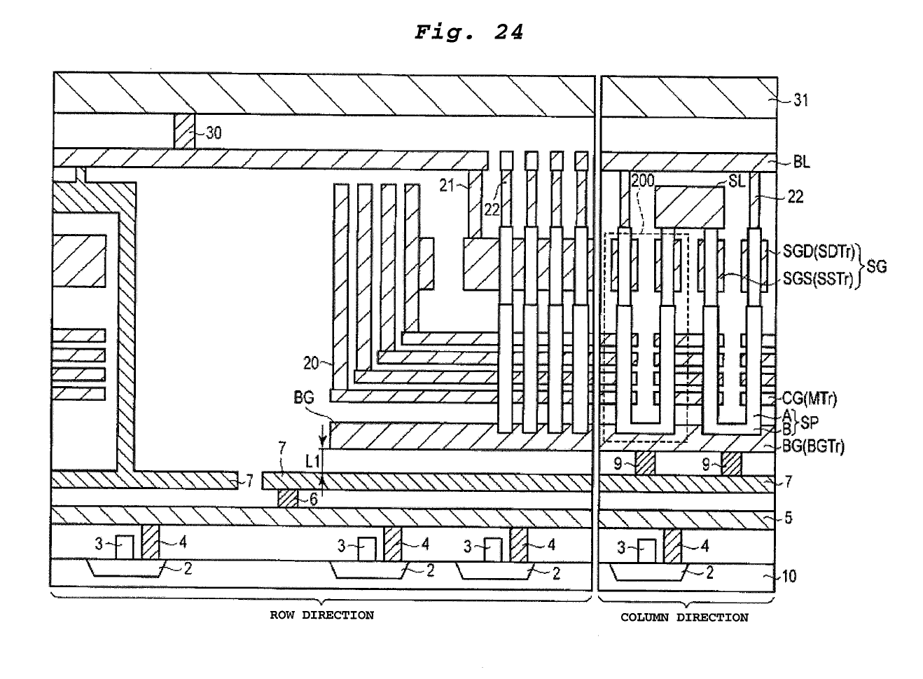

FIG. 21 to FIG. 23 show some examples of the structures of back gate layer BG and wiring layer 7 which are connected by multiple connection parts 9 in the row direction. FIG. 21 shows the structure of the regions excluding the one under the pipe (the edges of back gate layer BG) which provides multiple connection parts 9, FIG. 22 shows the structure of the region under the pipe which provides multiple connection parts 9, and FIG. 23 shows the structure of these above two areas where multiple connection parts 9 are formed.

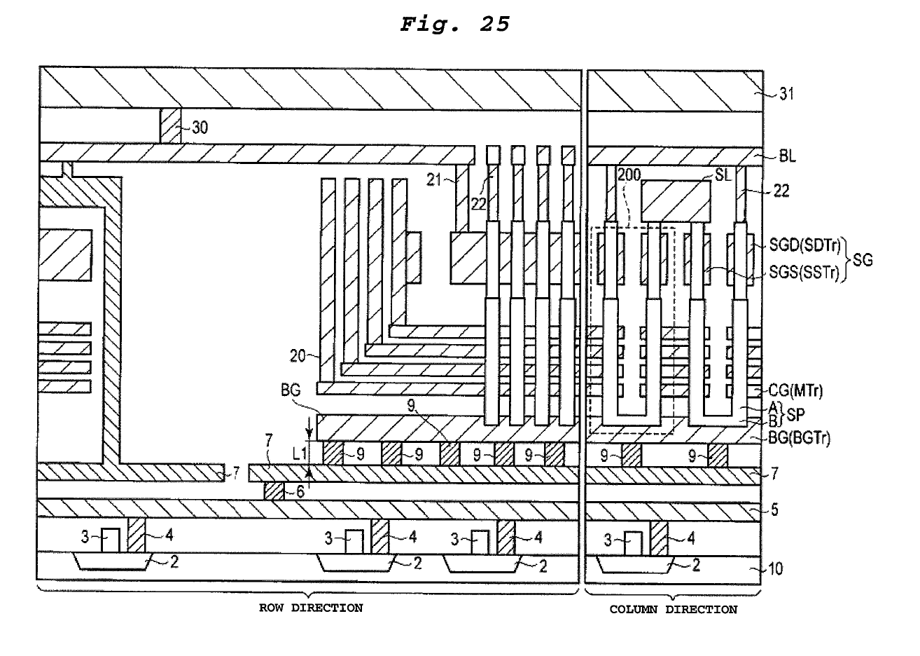

FIG. 24 shows the structure of back gate layer BG and wiring layer 7 connected by multiple connection parts 9 in the column direction.

FIG. 25 shows the structure of back gate layer BG and wiring part 7 connected by multiple connection parts 9, and shows the multiple connection parts 9 disposed in the row and the column directions.

Even in cases where back gate layer BG is structured by layers (such as Silicon layer which contains impurities) which have higher resistance than metal layer, forming connection parts 9 more than a certain number makes it possible to form channels in the pipes without applying a high voltage to back gate layer BG. And as has been explained above, connection parts 9 can be formed without particular constraint and it is possible to easily form more than a certain number of connection parts 9.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A non-volatile semiconductor memory device, comprising:
a peripheral circuit formed above a surface of a substrate and including multilayer wirings;
a plurality of memory strings formed above the peripheral circuit, and including a plurality of memory cells and a back gate transistor, the plurality of memory cells and a back gate transistor being connected in series;
multiple back gate layers, each of said back gate layers configured to function as a control electrode of the back gate transistor;
a first connection part connecting a lower surface of one of the back gate layers and an upper surface of the uppermost wiring layer of the multilayer wirings, wherein the first connection part are composed of semiconductor films; and
a barrier metal film disposed above the uppermost wiring layer.

2. The non-volatile semiconductor memory device of claim 1, wherein a barrier metal film is provided between the first connection part and the metal wiring.

3. The non-volatile semiconductor memory device of claim 2, wherein the plurality of memory strings includes a pair of columns, a second connection part connecting the pair of columns and a charge storage layer disposed at the sides of the columns and the columns are formed of silicon.

4. The non-volatile semiconductor memory device of claim 3, wherein the substrate is a silicon substrate.

5. The non-volatile semiconductor memory device of claim 4, wherein the substrate has a transistor formed thereon, and wherein a plug connects the substrate to a bottom surface of the bottommost wiring layer of the multilayer wirings.

6. The non-volatile semiconductor memory device of claim 1, wherein the first connection part has a length of 10-100 nm.

7. A non-volatile semiconductor memory device comprising:
a peripheral circuit disposed above a surface of a substrate and comprising multilayer wirings;
a plurality of memory cells disposed above the peripheral circuit, said memory cells being connected in series to form a plurality of memory strings, said memory strings being semiconductor layers and including a first connection part connecting a pair of columns and a charge storage layer disposed at the sides of the columns;
one or more back gate layers configured to function as control electrodes of a corresponding transistor which forms channels in the first connection part; and
a second connection part disposed between a lower surface of one of the back gate layers and the upper surface of the uppermost wiring layer of the multilayer wirings, the second connection part connecting the back gate layer and the uppermost wiring layer.

8. The non-volatile semiconductor memory device of claim 7, wherein the first connection part and conductive layers include semiconductor films.

9. The non-volatile semiconductor memory device of claim 8, wherein the uppermost wiring layer includes metal wiring.

10. The non-volatile semiconductor memory device of claim 9, wherein a barrier metal film is provided between the second connection part and the metal wiring.

11. The non-volatile semiconductor memory device of claim 10, wherein the columns are formed of silicon.

12. The non-volatile semiconductor memory device of claim 11, wherein the substrate is a silicon substrate.

13. The non-volatile semiconductor memory device of claim 12, wherein the substrate has a transistor formed thereon, and wherein a plug connects the substrate to a bottom surface of a bottommost wiring layer.

14. The non-volatile semiconductor memory device of claim 13, wherein the second connection part has a length of 10-100 nm.

15. A manufacturing method of a non-volatile semiconductor memory device, the manufacturing method comprising:
forming a peripheral circuit which includes a multilayer wiring on the surface of a substrate;
forming a first interlayer dielectric film on top of the peripheral circuit;
forming a connection hole through the first interlayer dielectric film which reaches an uppermost wiring layer of the multilayer wiring;
removing a part of the upper surface of the first interlayer dielectric film to form a groove in the first interlayer dielectric film;
forming a barrier metal film on one or more surfaces of the connection hole and surfaces of the first interlayer dielectric film; and
filling the connection hole and at least a portion of the groove with one or more conductive materials to form a gate layer in the groove and a conductive coupling in the connection hole, the conductive coupling providing electrical conductivity between the gate layer and the uppermost wiring layer of the multilayer wirings.

16. The manufacturing method of claim 15, wherein the barrier metal film is a tantalum nitride film.

17. The manufacturing method of claim 16, wherein the first interlayer dielectric film is a silicon oxide film.

18. The manufacturing method of claim 15, wherein the uppermost wiring layer of the multilayer wirings comprises a barrier metal layer at an upper surface of the uppermost wiring layer.

19. The manufacturing method of claim 18, wherein forming the peripheral circuit comprises forming the uppermost wiring layer of the multilayer wirings using the chemical mechanical polishing process.

20. The manufacturing method of claim 19, wherein the uppermost wiring layer of the multilayer wirings is formed at least partially of tungsten.
